(19) United States
(12) Patent Application Publication
(10) Pub. No.: US 2003/0136513 A1
(43) Pub. Date: Jul. 24, 2003

(54) Semiconductor manufacturing apparatus

(76) Inventors: Soon Ho Lee, Suwon (KR); Seong Sook Yi, Suwon (KR); Jin Seok Park, Suwon (KR); Sung Up Yoon, Kunpo (KR); Jong Sik Kim, Suwon (KR); Byung Chul Kim, Osan (KR); Byung Deok Yoo, Koyang (KR)

Correspondence Address: WEINER & BURT, P.C., P.O. BOX 186, HARRISVILLE, MI, 48740, US

(21) Appl. No.: 10/055,591

(22) Filed: Jan. 22, 2002

(30) Foreign Application Priority Data
Jan. 22, 2001 (KR) 2001-3619
Dec. 13, 2001 (KR) 2001-78830

(51) Int. Cl. C23F 1/00; C23C 16/00

(52) U.S. Cl. 156/345.31; 118/715

(57) ABSTRACT

There is provided a semiconductor manufacturing apparatus comprising: a cassette station 16 in which wafers 18 are loaded; a stand-by conveying robot 10 for taking the wafers 18 out of the cassette station 16; a load lock chamber 12 in which the wafers 18 taken by the stand-by conveying robot 10 are accommodated; and a reaction chamber 14 placed in contact with the load lock chamber 12, the reaction chamber 14 having a shuttle blade 20 for drawing the wafers accommodated in the load lock chamber out of the load lock chamber 12 in a vacuum state and loading etched wafers in the load lock chamber, a rotary robot 26 for rotatively transferring the wafers taken out of the load lock chamber to be placed on the shuttle blade 20, and a heater stage 24 for etching the wafers transferred by the rotary robot 26 using a plasma generator 28, in which a pre-heating part 22 is placed above the shuttle blade 20, for pre-heating the wafers transferred into the reaction chamber 14 from the load lock chamber 12 before they are moved to the heater stage 24 in order to improve etch rate. Accordingly, etch processing time is shortened and productivity is maximized.

### BACKGROUND OF THE INVENTION

1. Field of the Invention

The present invention generally relates to a semiconductor manufacturing apparatus and, more particularly, to a semiconductor manufacturing apparatus capable of effectively etching a plurality of wafers within a short period of time through a series of processes of drawing a wafer from a cassette station to load it in a load lock chamber, transferring this wafer to a reaction chamber to etch it, and then unloading the etched wafer through the load lock chamber.

2. Description of the Related Art

Microscopic processing for manufacturing a semiconductor integrated circuit is performed by etching a photoresist film formed through exposure and development and a layer formed therebelow. After the etching process, the photoresist film used as a mask is removed from a wafer through a dry etching using gases or a wet etching using liquid chemical.

A conventional semiconductor manufacturing apparatus includes a load lock chamber capable of loading fifty wafers, a stand-by conveying robot having twenty-five blades for drawing twenty-five wafers from a cassette station and conveying them, and a reaction chamber where wafers are etched. The reaction chamber is constructed of a shuttle blade for carrying etched wafers and non-etched wafers between the reaction chamber and the load clock chamber, seven pins which have a common center hub and rotatively transfer wafers sent to the reaction chamber by the shuttle blade to a heater stage, three pairs of plasma generators each of which combined with each other in parallel, and six heater stages.

However, the aforementioned conventional semiconductor manufacturing apparatus becomes many problems as the wafer becomes large-sized (300 mm). That is, twenty-five wafers that are expensive may be all destroyed even if the flat zone of any wafer is out of the normal position thereof because the stand-by conveying robot conveys the twenty-five wafers simultaneously. In addition, one plasma generator is used for two heater stages in parallel so that wafer etch rate is slow. Furthermore, additional wafers cannot be accommodated in the load lock chamber because the apparatus has only one load lock chamber, and the entire apparatus cannot be used when the load lock chamber has a problem. Moreover, an additional pre-heating period of time is required for making the surface of the wafer be adapted for optimized etching when the wafer is put on the heater stage. Furthermore, since the apparatus does not has a device for removing remnants on the backside of the wafer, an additional cleaning process is needed after the etching is finished.

### SUMMARY OF THE INVENTION

It is, therefore, an object of the present invention to provide a semiconductor manufacturing apparatus, adapted for minimizing loss of wafer, which employs a plurality of load lock chambers and plasma generators for stabilized and rapid operations, and has a pre-heating part, set inside a reaction chamber, for separately controlling the temperature before a wafer is put on a heater stage to improve the etch rage of wafer, and includes a device for eliminating remnants on the backside of the wafer to omit an additional cleaning process.

To accomplish the object of the present invention, there is provided a semiconductor manufacturing apparatus comprising: a cassette station in which wafers are loaded; a stand-by conveying robot for taking the wafers out of the cassette station; a load lock chamber in which the wafers taken by the stand-by conveying robot are accommodated; and a reaction chamber placed in contact with the load lock chamber, the reaction chamber having a shuttle blade for drawing the wafers accommodated in the load lock chamber out of the load lock chamber in a vacuum state and loading etched wafers in the load lock chamber, a rotary robot for rotatively transferring the wafers taken out of the load lock chamber to be placed on the shuttle blade, and a heater stage for etching the wafers transferred by the rotary robot using a plasma generator, in which the load lock chamber is placed at each of both sides of the reaction chamber adjacent to the stand-by conveying robot so that the wafers transferred by the stand-by conveying robot can be continuously loaded into or taken out of the load lock chamber even in the process of etching other wafers.

To accomplish the object of the present invention, there is provided a semiconductor manufacturing apparatus comprising: a cassette station in which wafers are loaded; a stand-by conveying robot for taking the wafers out of the cassette station; a load lock chamber in which the wafers taken by the stand-by conveying robot are accommodated; and a reaction chamber placed in contact with the load lock chamber, the reaction chamber having a shuttle blade for drawing the wafers accommodated in the load lock chamber out of the load lock chamber in a vacuum state and loading etched wafers in the load lock chamber, a rotary robot for rotatively transferring the wafers taken out of the load lock chamber to be placed on the shuttle blade, and a heater stage for etching the wafers transferred by the rotary robot using a plasma generator, in which the stand-by conveying robot is placed between the cassette station and the load lock chamber and it has a rotatable arm for taking the wafers out of the cassette station and loading them in the load lock chamber and a plurality of blades, formed at the front end of the arm, for carrying a plurality of wafers.

It is preferable that the blades of the arm make the wafers put on the arm according to vacuum absorption.

Further, the present invention provides a semiconductor manufacturing apparatus comprising: a cassette station in which wafers are loaded; a stand-by conveying robot for taking the wafers out of the cassette station; a load lock chamber having a wafer holder in which the wafers taken by the stand-by conveying robot are accommodated; and a reaction chamber placed in contact with the load lock chamber, the reaction chamber having a shuttle blade for drawing the wafers accommodated in the load lock chamber out of the load lock chamber in a vacuum state and loading etched wafers in the load lock chamber, a rotary robot for rotatively transferring the wafers taken out of the load lock chamber to be placed on the shuttle blade, and a heater stage for etching the wafers transferred by the rotary robot using a plasma generator, in which the wafer holder can be moved upward and downward to permit the wafers horizontally transferred by the stand-by conveying robot or shuttle blade to be sequentially loaded into or taken out of the wafer holder, and it can be rotated to axially rotate the wafers loaded or taken toward the reaction chamber or stand-by conveying robot to allow the stand-by conveying robot or shuttle blade to be able to easily draw the wafers therefrom according to horizontal movement.

Also, the present invention provides a semiconductor manufacturing apparatus comprising: a cassette station in which wafers are loaded; a stand-by conveying robot for taking the wafers out of the cassette station; a load lock chamber in which the wafers taken by the stand-by conveying robot are accommodated; and a reaction chamber placed in contact with the load lock chamber, the reaction chamber having a shuttle blade for drawing the wafers accommodated in the load lock chamber out of the load lock chamber in a vacuum state and loading etched wafers in the load lock chamber, a rotary robot for rotatively transferring the wafers taken out of the load lock chamber to be placed on the shuttle blade, and a heater stage for etching the wafers transferred by the rotary robot using a plasma generator, in which the shuttle blade is operated by an air cylinder to transfer the wafers loaded in the wafer holder of the load lock chamber to the reaction chamber and transfer etched wafers back to the load lock chamber.

The present invention further provides a semiconductor manufacturing apparatus comprising: a cassette station in which wafers are loaded; a stand-by conveying robot for taking the wafers out of the cassette station; a load lock chamber in which the wafers taken by the stand-by conveying robot are accommodated; and a reaction chamber placed in contact with the load lock chamber, the reaction chamber having a shuttle blade for drawing the wafers accommodated in the load lock chamber out of the load lock chamber in a vacuum state and loading etched wafers in the load lock chamber, a rotary robot for rotatively transferring the wafers taken out of the load lock chamber to be placed on the shuttle blade, and a heater stage for etching the wafers transferred by the rotary robot using a plasma generator, in which a pre-heating part is placed above the shuttle blade, for pre-heating the wafers transferred into the reaction chamber from the load lock chamber before they are moved to the heater stage in order to improve etch rate.

Moreover, there is provided a semiconductor manufacturing apparatus comprising: a cassette station in which wafers are loaded; a stand-by conveying robot for taking the wafers out of the cassette station; a load lock chamber in which the wafers taken by the stand-by conveying robot are accommodated; and a reaction chamber placed in contact with the load lock chamber, the reaction chamber having a shuttle blade for drawing the wafers accommodated in the load lock chamber out of the load lock chamber in a vacuum state and loading etched wafers in the load lock chamber, a rotary robot for rotatively transferring the wafers taken out of the load lock chamber to be placed on the shuttle blade, and a heater stage for etching the wafers transferred by the rotary robot using a plasma generator, in which the plasma generator is set corresponding to each heater stage to allow different gases or the same gas to be introduced into the reaction chamber for plasma process with a controller.

There is also provided a semiconductor manufacturing apparatus comprising: a cassette station in which wafers are loaded; a stand-by conveying robot for taking the wafers out of the cassette station; a load lock chamber in which the wafers taken by the stand-by conveying robot are accommodated; and a reaction chamber placed in contact with the load lock chamber, the reaction chamber having a shuttle blade for drawing the wafers accommodated in the load lock chamber out of the load lock chamber in a vacuum state and loading etched wafers in the load lock chamber, a rotary robot for rotatively transferring the wafers taken out of the load lock chamber to be placed on the shuttle blade, and a heater stage for etching the wafers transferred by the rotary robot using a plasma generator, in which the reaction chamber has multiple heater stages, each heater stage being capable of controlling temperature independently.

It is preferable that an auxiliary plasma generator is set under a predetermined part of the reaction chamber in order to remove remnants attached onto the backside of a wafer before the wafer is placed on the shuttle blade to be transferred.

### BRIEF DESCRIPTION OF THE DRAWINGS

Further objects and advantages of the invention can be more fully understood from the following detailed description taken in conjunction with the accompanying drawings, in which:

FIG. 1 is a perspective view of a semiconductor manufacturing apparatus according to the present invention;

FIG. 2 is a side view of the semiconductor manufacturing apparatus according to the present invention;

FIG. 3 is a plan view of the semiconductor manufacturing apparatus according to the present invention;

FIGS. 4a and 4b are lateral cross-sectional views illustrating the operation state of a shuttle blade of the semiconductor manufacturing apparatus according to the present invention;

FIG. 5 is a perspective view of a stand-by conveying robot of the semiconductor manufacturing apparatus according to the present invention; and

FIG. 6 is a side view showing an embodiment of the semiconductor manufacturing apparatus according to the present invention.

### DETAILED DESCRIPTION OF THE PREFERRED EMBODIMENT

The present invention will now be described in connection with preferred embodiments with reference to the accompanying drawings.

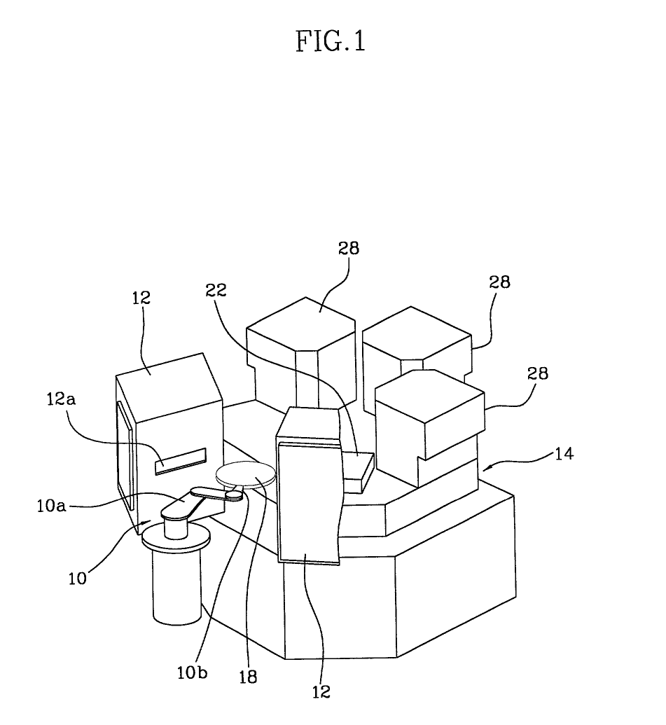

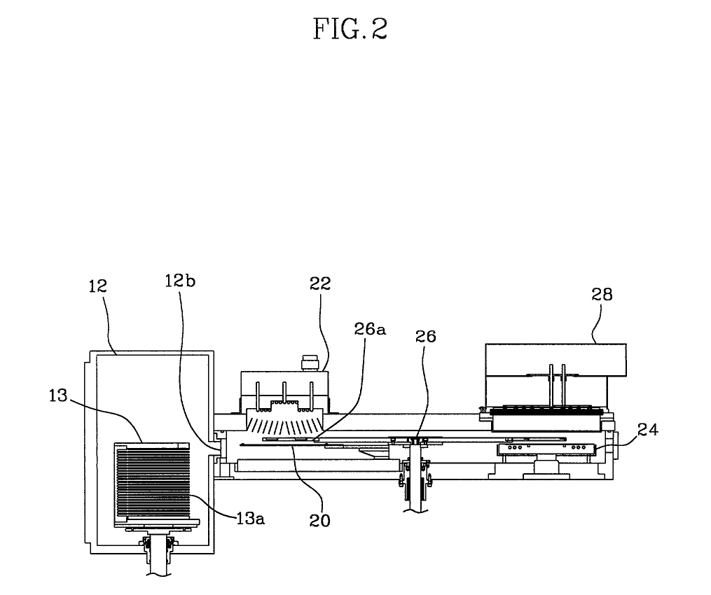

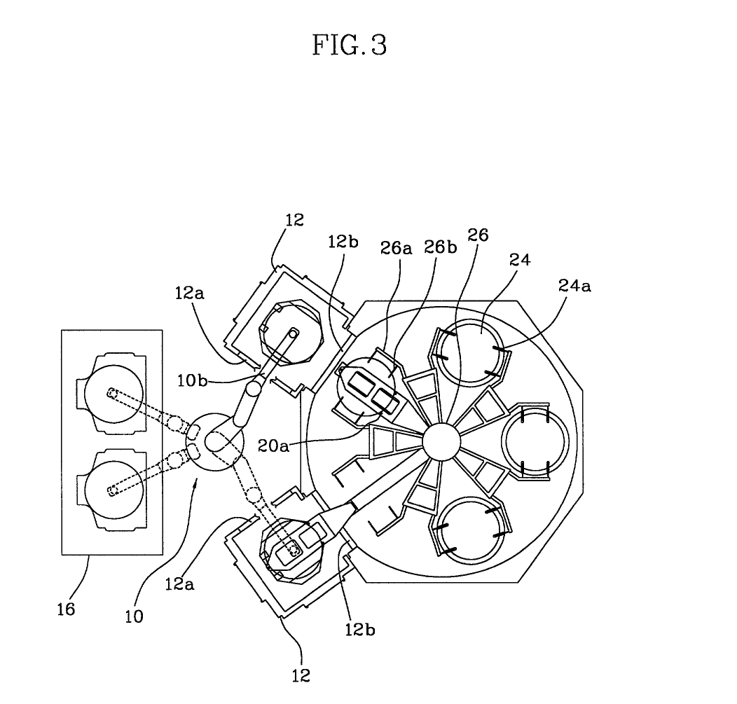

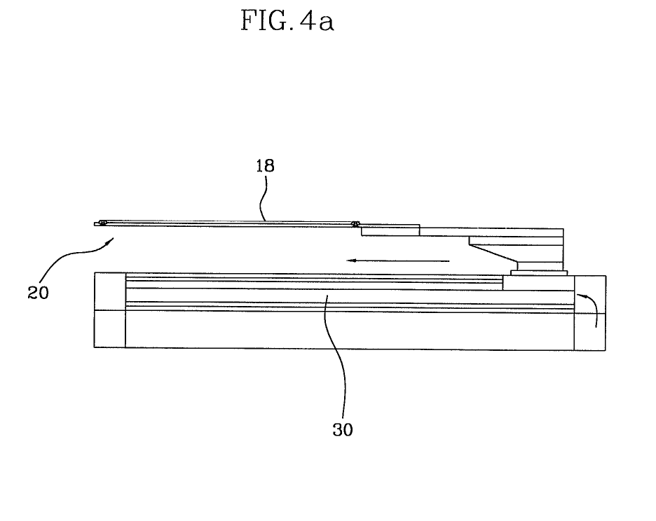

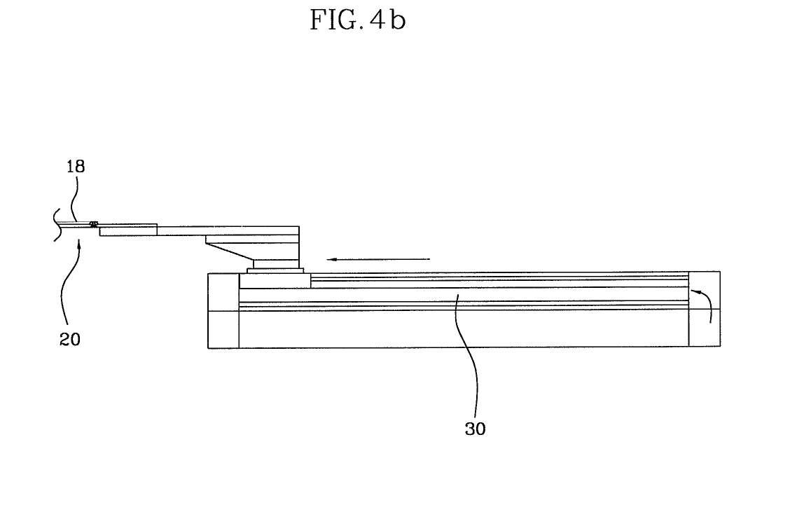

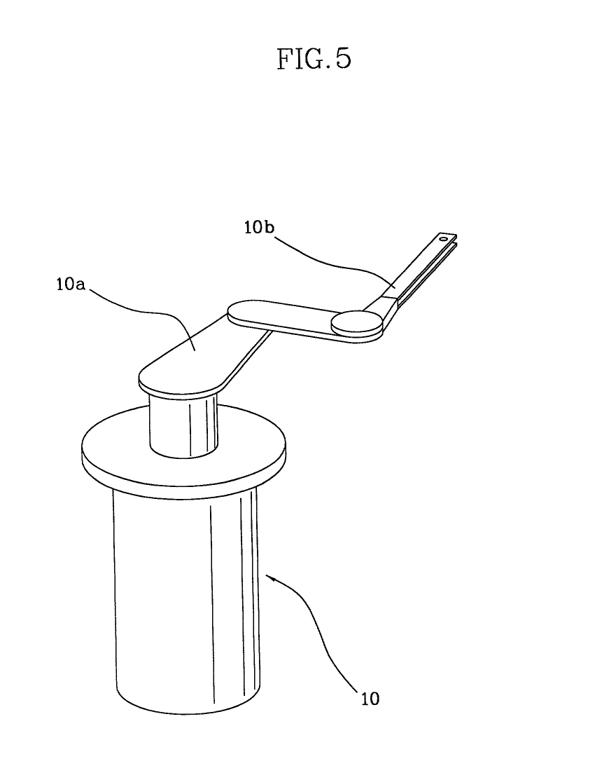

Referring to FIG. 1 to 5, a semiconductor manufacturing apparatus of the invention includes a stand-by conveying robot 10, a load lock chamber 12 and a reaction chamber 14. The stand-by conveying robot 10 has an arm 10a, which is placed between a cassette station 16 and a the load lock chamber 12 to draw a wafer 18 out of the cassette station 16 and load it in the load lock chamber 12 and is capable of being axially rotated, folded and unfolded, and a plurality of blades 10b for vacuum-adsorbing the wafer 18 on the tip of the arm 10a. Here, it is preferable that the stand-by conveying robot has two blades 10b set upper and lower sides for stably conveying the wafer 18.

The load lock chamber 12 in a box form is placed in contact with each of both sides of the reaction chamber 14 corresponding to the stand-by conveying robot 10, and has gates 12a and 12b formed at sides facing the outside and the reaction chamber 14, respectively. Each load lock chamber 12 has a wafer holder 13 for accommodating the wafer 18 thereinside. The wafer holder 13 has a plurality of slits 13a for accommodating a plurality of wafers, and sequentially accepts the wafers carried by the stand-by conveying robot 10 in vertical direction. Furthermore, the wafer holder 13 can be moved upward and downward so that the wafer can be put on the top side of a shuttle blade 20 placed inside the reaction chamber 20 when the shuttle blade 20 enters thereinto. In addition, the wafer holder 13 can be rotated such that the shuttle blade can easily takes the wafer 18 accommodated in the wafer holder out of it.

The gate 12a of the load lock chamber, facing the outside, is being opened while the stand-by conveying robot 10 loads the wafer 18 in the load lock chamber and closed when loading of wafer has been finished. The gate 12b facing the reaction chamber 14 is being closed during the loading of wafer 18 and opened when the external gate 12a is closed and the load lock chamber 12 becomes vacuum state after the completion of the wafer loading.

The reaction chamber 14 includes a pair of shuttle blades 20 that are horizontally moved to the load lock chamber 12 to draw the wafer 18 out of the load lock chamber 12, a pre-heating part 22 set above the shuttle blades 20 to pre-heat the wafer 18 when the shuttle blades 20 return to the initial position after they has drawn the wafer 18 out of the load lock chamber, a rotary robot 26 for rotatively transferring the wafer 18 to a heater stage 24 when the pre-heating by the pre-heating part 22 has been finished, a plurality of heater stages 24 on which the wafers transferred by the rotary robot 26 are placed, and plasma generators 28 respectively corresponding to the heater stages 24 to generate gas plasma for etching the wafer 18. Parts of the outer side of the reaction chamber 14 are connected with the pair of load lock chambers 12.

The shuttle blades 20 are in the shape of plate on which the wafer 18 can be placed, and set inside the reaction chamber 14, respectively corresponding to the load lock chambers 12. The shuttle blades 20 can be horizontally moved by an air cylinder 30 so as to enter into the load lock chambers 12 to take the wafer 18 therefrom when the load lock chambers 12 become vacuum state so that the gate 12b is opened and then return to the initial state. On the top surface of the shuttle blades 20, there are formed a plurality of fixing protrusions 20a for fixing the wafer 18 put on the shuttle blades.

The pre-heating part 22, placed above the shuttle blades 20, pre-heats the wafer 18 carried by the shuttle blade 20 from the load lock chamber 12 before the wafer is transferred to the heater stage 24 to omit additional heat treatment time in the heat stage 24 and improve etch rate. A halogen lamp is preferably used as the heat source of the pre-heating part 22.

The rotary robot 26 is constructed of a plurality of rotary arms 26a and transfer pins 26b that turn on the axis at the center of the reaction chamber. The rotary robot 26 can be moved upward and downward and rotated. By doing so, it lifts the wafer 18 taken by the shuttle blade 20, rotatively transfers it to the heater stage 24 placed at the side thereof and put it down on the heater stage where the wafer 18 is etched. In addition, the rotary robot 26 lifts the etched wafer, rotatively transfers it and put it on the shuttle blade 20 to allow the wafer to be discharged through the load clock chamber 12 to the outside. The plurality of transfer pins 26b by which the wafer 18 is put on the rotary arm 26a of the rotary robot 26 are formed at the end of the rotary arm 26a.

The heater stage 24 has the form of disk on which the wafer 18 transferred by the rotary arm 26a of the rotary robot 26 is put, and heats the wafer 18 placed thereon according to etching conditions. A plurality of through-holes 24a through which the transfer pins 26b of the rotary arm 26a penetrate to allow only the wafer 18 to be placed on the heater stage 24 are formed at the circumferenctial side of the heater stage 24, corresponding to the transfer pins 26b of the rotary arm 26a.

Each plasma generator 28 is placed above each heater stage 24 to allow different gases or the same gas to be introduced into the reaction chamber for plasma process independently with a controller (not shown).

In the semiconductor manufacturing apparatus having the above-described configuration according to the present invention, the stand-by conveying robot 10 placed between the cassette station 16 and the load lock chamber 12 takes wafers 18 out of the cassette station 16 when the gate 12a facing the outside is opened, and transfers the wafers into the load lock chamber 12 having the wafer holder 13. The wafer holder 13 moves up and down under the control of a motor (not shown) to permit the wafers 18 carried by the stand-by conveying robot 10 or shuttle blade 20 to be sequentially accommodated in or taken out of a desired slit 13a thereof. In addition, the wafer holder 13 axially rotates the wafers accommodated or taken toward the reaction chamber 14 or stand-by conveying robot 10 to allow the shuttle blade 20 or stand-by conveying robot 10 to horizontally move to easily accept or draw the wafers.

The stand-by conveying robot 10 moves a plurality of wafers from the cassette station 16 to the pair of load lock chambers 12 because it has a plurality of vacuum blades 10b formed at one arm 10a thereof. When there are other wafers required to be processed while the plurality of wafers 18 are loaded in one of the pair of load lock chambers and then etched in the reaction chamber 12, the stand-by conveying robot 10 moves the wafers to be processed into the other load lock chamber, vacuumizes it and makes it be in stand by state for continuous process. Then, when all of the wafers in the reaction chamber have been etched to be accepted by the former load lock chamber, the wafers in the stand by state in the latter load lock chamber are transferred to the reaction chamber 14 to be processed. Here, it is preferable that the stand-by conveying robot 10 has two blades 10b formed at the arm 10a thereof and these two blades 10b transfer two wafers.

After the gate 12a facing the outside is closed, the wafers 18 moved to the load lock chamber 12 by the stand-by conveying robot 10 are rotated by the wafer holder 13 to be transferred toward the reaction chamber 14. The load lock chamber 12 is required to be the same vacuum state as that of the reaction chamber 14 in order to move the wafers 18 to the reaction chamber 14.

When the load lock chamber 12 becomes the same vacuum state of the reaction chamber 14, the gate 12b facing the reaction chamber 14 is opened and the shuttle blade 20 placed inside the reaction chamber 14 horizontally moves the wafers 18 into the reaction chamber 14. Here, the shuttle blade 20 is moved according to air pumping and it preferably employs an air cylinder 20 whose speed can be controlled.

The wafers 18 transferred into the reaction chamber 14 are placed in a load stage state. These wafers 18 in the load stage state are pre-heated by the pre-heating part 22 and then lifted by the transfer pins 26b of the rotary arm 26a of the rotary robot 26 to be etched while sequentially moved to the heater stage24. Meantime, the shuttle blade 20 accommodates processed wafers in the wafer holder 13 inside the load lock chamber 12 while the wafers are processed on the heater stage 24, and brings wafers which are not processed yet inside the wafer holder 13 to the load stage of the reaction chamber 14 to allow them to be pre-heated by the pre-heating part 22. Here, the heater stage 24 is capable of controlling temperature up to 300° C. For reference, the temperature suitable for removal of photoresist is 50˜250° C.

The multiple heater stages 24 respectively have multiple plasma generators 28 for independent processing to be able to etch photoresist. Each heater stage 24 can control temperature independently, and introduce different gases or same gas in the reaction chamber 14 depending on process conditions and control power for generating plasma with individual plasma generator 28. Accordingly, photoresist difficult to remove left after ion implantation with a high ion concentration can be eliminated effectively.

The wafers 18 from which photoresist has bee removed on the heater stage 24 are moved back to the load stage state by the rotary robot 26 and etched wafers are put in the wafer holder 13 of the load lock chamber 12 through the shuttle blade 20.

When all of the wafers loaded in the load lock chambers has been etched, the gate 12b facing the reaction chamber 14 is closed and nitrogen gas is introduced into the load lock chamber to turn it from the vacuum state into the atmospheric state so that the stand-by conveying robot 10 can carry the etched wafers to the cassette station 16. Subsequently, the gate 12a connected with the stand-by conveying robot 10 is opened and this stand-by conveying robot 10 moves the etched wafers to the initial cassette station 16 to thereby finish one processing cycle.

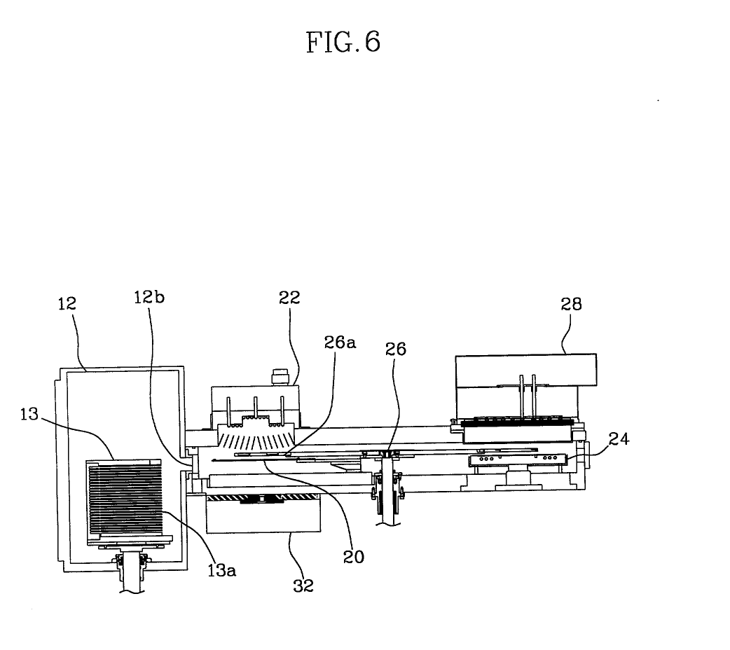

FIG. 6 shows an embodiment of the semiconductor manufacturing apparatus according to the present invention. Referring to FIG. 6, an auxiliary plasma generator 32 is set right under the pre-heating part 22 to remove remnants on the backside of the wafer 18 while the wafer is pre-heated. This eliminates an additional cleaning process for removing the remnants on the backside of the wafer after the wafer has been etched. Here, radio frequencies from 13.56 MHz to 24.12 GHz, industrial frequency band, are suitable for the power of the auxiliary plasma generator 32.

As described above, the semiconductor manufacturing apparatus of the present invention has a pair of load lock chambers to transfer wafers stably and rapidly and separately pre-heats the wafers in the load stage state before they are moved to the heater stage inside the reaction chamber to shorten etching process time. Furthermore, differentiated gas plasma etch processes are simultaneously performed for the wafers while the wafers are sequentially transferred to the plurality of heater stages each of which can control temperature individually to improve process capability and maximize productivity. Moreover, remnants on the backsides of the wafers can be eliminated during the etching processes to omit additional cleaning processes.

Although specific embodiments including the preferred embodiment have been illustrated and described, it will be obvious to those skilled in the art that various modifications may be made without departing from the spirit and scope of the present invention, which is intended to be limited solely by the appended claims.

What is claimed is:

1. A semiconductor manufacturing apparatus comprising: a cassette station in which wafers are loaded; a stand-by conveying robot for taking the wafers out of the cassette station; a load lock chamber in which the wafers taken by the stand-by conveying robot are accommodated; and a reaction chamber placed in contact with the load lock chamber, the reaction chamber having a shuttle blade for drawing the wafers accommodated in the load lock chamber out of the load lock chamber in a vacuum state and loading etched wafers in the load lock chamber, a rotary robot for rotatively transferring the wafers taken out of the load lock chamber to be placed on the shuttle blade, and a heater stage for etching the wafers transferred by the rotary robot using a plasma generator,
wherein the load lock chamber is placed at each of both sides of the reaction chamber adjacent to the stand-by conveying robot so that the wafers transferred by the stand-by conveying robot can be continuously loaded into or taken out of the load lock chamber even in the process of etching other wafers.

2. A semiconductor manufacturing apparatus comprising: a cassette station in which wafers are loaded; a stand-by conveying robot for taking the wafers out of the cassette station; a load lock chamber in which the wafers taken by the stand-by conveying robot are accommodated; and a reaction chamber placed in contact with the load lock chamber, the reaction chamber having a shuttle blade for drawing the wafers accommodated in the load lock chamber out of the load lock chamber in a vacuum state and loading etched wafers in the load lock chamber, a rotary robot for rotatively transferring the wafers taken out of the load lock chamber to be placed on the shuttle blade, and a heater stage for etching the wafers transferred by the rotary robot using a plasma generator,
wherein the stand-by conveying robot is placed between the cassette station and the load lock chamber and it has a rotatable arm for taking the wafers out of the cassette station and loading them in the load lock chamber and a plurality of blades, formed at the front end of the arm, for carrying a plurality of wafers.

3. The semiconductor manufacturing apparatus as claimed in claim 2, wherein the blades of the arm make the wafers put on the arm according to vacuum absorption.

4. A semiconductor manufacturing apparatus comprising: a cassette station in which wafers are loaded; a stand-by conveying robot for taking the wafers out of the cassette station; a load lock chamber having a wafer holder in which the wafers taken by the stand-by conveying robot are accommodated; and a reaction chamber placed in contact with the load lock chamber, the reaction chamber having a shuttle blade for drawing the wafers accommodated in the load lock chamber out of the load lock chamber in a vacuum state and loading etched wafers in the load lock chamber, a rotary robot for rotatively transferring the wafers taken out of the load lock chamber to be placed on the shuttle blade, and a heater stage for etching the wafers transferred by the rotary robot using a plasma generator,
wherein the wafer holder can be moved upward and downward to permit the wafers horizontally transferred by the stand-by conveying robot or shuttle blade to be sequentially loaded into or taken out of the wafer holder, and it can be rotated to axially rotate the wafers loaded or taken toward the reaction chamber or stand-by conveying robot to allow the stand-by conveying robot or shuttle blade to be able to easily draw the wafers therefrom according to horizontal movement.

5. A semiconductor manufacturing apparatus comprising: a cassette station in which wafers are loaded; a stand-by conveying robot for taking the wafers out of the cassette station; a load lock chamber in which the wafers taken by the stand-by conveying robot are accommodated; and a reaction chamber placed in contact with the load lock chamber, the reaction chamber having a shuttle blade for drawing the wafers accommodated in the load lock chamber out of the load lock chamber in a vacuum state and loading etched wafers in the load lock chamber, a rotary robot for rotatively transferring the wafers taken out of the load lock chamber to be placed on the shuttle blade, and a heater stage for etching the wafers transferred by the rotary robot using a plasma generator,
wherein the shuttle blade is operated by an air cylinder to transfer the wafers loaded in the wafer holder of the load lock chamber to the reaction chamber and transfer etched wafers back to the load lock chamber.

6. A semiconductor manufacturing apparatus comprising: a cassette station in which wafers are loaded; a stand-by conveying robot for taking the wafers out of the cassette station; a load lock chamber in which the wafers taken by the stand-by conveying robot are accommodated; and a reaction chamber placed in contact with the load lock chamber, the reaction chamber having a shuttle blade for drawing the wafers accommodated in the load lock chamber out of the load lock chamber in a vacuum state and loading etched wafers in the load lock chamber, a rotary robot for rotatively transferring the wafers taken out of the load lock chamber to be placed on the shuttle blade, and a heater stage for etching the wafers transferred by the rotary robot using a plasma generator,
wherein a pre-heating part is placed above the shuttle blade, for pre-heating the wafers transferred into the reaction chamber from the load lock chamber before they are moved to the heater stage in order to improve etch rate.

7. A semiconductor manufacturing apparatus comprising: a cassette station in which wafers are loaded; a stand-by conveying robot for taking the wafers out of the cassette station; a load lock chamber in which the wafers taken by the stand-by conveying robot are accommodated; and a reaction chamber placed in contact with the load lock chamber, the reaction chamber having a shuttle blade for drawing the wafers accommodated in the load lock chamber out of the load lock chamber in a vacuum state and loading etched wafers in the load lock chamber, a rotary robot for rotatively transferring the wafers taken out of the load lock chamber to be placed on the shuttle blade, and a heater stage for etching the wafers transferred by the rotary robot using a plasma generator,
wherein the plasma generator is set corresponding to each heater stage to allow different gases or the same gas to be introduced into the reaction chamber for plasma process with a controller.

8. A semiconductor manufacturing apparatus comprising: a cassette station in which wafers are loaded; a stand-by conveying robot for taking the wafers out of the cassette station; a load lock chamber in which the wafers taken by the stand-by conveying robot are accommodated; and a reaction chamber placed in contact with the load lock chamber, the reaction chamber having a shuttle blade for drawing the wafers accommodated in the load lock chamber out of the load lock chamber in a vacuum state and loading etched wafers in the load lock chamber, a rotary robot for rotatively transferring the wafers taken out of the load lock chamber to be placed on the shuttle blade, and a heater stage for etching the wafers transferred by the rotary robot using a plasma generator,
wherein the reaction chamber has multiple heater stages, each heater stage being capable of controlling temperature independently.

9. The semiconductor manufacturing apparatus as claimed in claim 1, wherein an auxiliary plasma generator is set under a predetermined part of the reaction chamber in order to remove remnants attached onto the backside of a wafer before the wafer is placed on the shuttle blade to be transferred.

10. The semiconductor manufacturing apparatus as claimed in claim 2, wherein an auxiliary plasma generator is set under a predetermined part of the reaction chamber in order to remove remnants attached onto the backside of a wafer before the wafer is placed on the shuttle blade to be transferred.

11. The semiconductor manufacturing apparatus as claimed in claim 3, wherein an auxiliary plasma generator is set under a predetermined part of the reaction chamber in order to remove remnants attached onto the backside of a wafer before the wafer is placed on the shuttle blade to be transferred.

12. The semiconductor manufacturing apparatus as claimed in claim 4, wherein an auxiliary plasma generator is set under a predetermined part of the reaction chamber in order to remove remnants attached onto the backside of a wafer before the wafer is placed on the shuttle blade to be transferred.

13. The semiconductor manufacturing apparatus as claimed in claim 5, wherein an auxiliary plasma generator is set under a predetermined part of the reaction chamber in order to remove remnants attached onto the backside of a wafer before the wafer is placed on the shuttle blade to be transferred.

14. The semiconductor manufacturing apparatus as claimed in claim 6, wherein an auxiliary plasma generator is set under a predetermined part of the reaction chamber in order to remove remnants attached onto the backside of a wafer before the wafer is placed on the shuttle blade to be transferred.

15. The semiconductor manufacturing apparatus as claimed in claim 7, wherein an auxiliary plasma generator is set under a predetermined part of the reaction chamber in order to remove remnants attached onto the backside of a wafer before the wafer is placed on the shuttle blade to be transferred.

16. The semiconductor manufacturing apparatus as claimed in claim 8, wherein an auxiliary plasma generator is set under a predetermined part of the reaction chamber in order to remove remnants attached onto the backside of a wafer before the wafer is placed on the shuttle blade to be transferred.
